(19) United States
(12) Patent Application Publication
(10) Pub. No.: US 2019/0085441 A1
(43) Pub. Date: Mar. 21, 2019

(54) Hermetic Sealed Crucible And Vapor Deposition Method Using The Same

(71) Applicant: BOE TECHNOLOGY GROUP CO., LTD., Beijing (CN)

(72) Inventor: Yongqi SHEN, Beijing (CN)

(21) Appl. No.: 16/038,775

(22) Filed: Jul. 18, 2018

(30) Foreign Application Priority Data
Sep. 21, 2017 (CN) 201710859094.1

(51) Int. Cl. C23C 14/24; H05K 5/06; C23C 14/56

(52) U.S. Cl. CPC C23C 14/243; C23C 14/56; H05K 5/069; H05K 5/068

(57) ABSTRACT

The disclosure relates to a hermetic sealed crucible comprising a crucible body with a cavity for placing materials, a cover plate for covering and sealing the cavity. The crucible further comprises a pneumatic driver which is connected to the cover plate and drives the cover plate to move relative to the cavity. The pneumatic device comprises a cylinder in which a spacer is arranged, the spacer being configured to move relative to the cylinder and divide the cylinder into a first air chamber provided with a first valve, and a second air chamber provided with a second valve, the spacer being provided with a drive rod connected to the cover plate at a side in the first air chamber, the drive rod being configured to drive the cover plate to move to close or open the cavity. The disclosure further relates to a vapor deposition method using the crucible.

### CROSS-REFERENCE TO RELATED APPLICATION

This application claims the benefit and priority of Chinese Patent Application No. 201710859094.1 filed Sep. 21, 2017. The entire disclosure of the above application is hereby incorporated by reference.

### FIELD

The present disclosure relates to vapor deposition field, and in particular to a hermetic sealed crucible in this field that can be sealed and opened automatically.

### BACKGROUND

This section provides background information related to the present disclosure which is not necessarily prior art.

Currently, the process of manufacturing display panels by using vapor deposition technology is carried out in such a manner that a vapor deposition material is placed in an open crucible which then is placed in a processing chamber of a device for vapor deposition.

### SUMMARY

This section provides a general summary of the disclosure, and is not a comprehensive disclosure of its full scope or all of its features.

In order to overcome one or more of the above defects, the present disclosure provides a hermetic sealed crucible, which is used in cooperation with a glove box and capable of being closed automatically and opened in the glove box to be filled with materials. The present disclosure further relates to a method for vapor deposition using the hermetic sealed crucible.

According to an aspect, the present disclosure relates to a hermetic sealed crucible, comprising:
a crucible body with a cavity for placing materials;
a cover plate for covering and sealing the cavity of the crucible body,

wherein the hermetic sealed crucible further comprises a pneumatic driver which is connected to the cover plate and drives the cover plate to move relative to the cavity in the crucible body to open and close the cavity in the crucible body,

the pneumatic driver is configured in such a manner that it comprises a cylinder in which a spacer is arranged, the spacer being configured to move relative to the cylinder under pressure and divide the cylinder into a first air chamber provided with a first valve in communication with ambient, and a second air chamber provided with a second valve in communication with the ambient, the spacer being provided with a drive rod connected to the cover plate at a side in the first air chamber, the drive rod being configured to drive the cover plate to move to close or open the cavity on the crucible body.

The hermetic sealed crucible of the present disclosure may manifest the following advantageous aspects.

Preferably, the first valve is replaced by an opening such that the first air chamber is constantly in communication with the ambient.

Preferably, the drive rod is fixedly connected to the cover plate at a side in the first air, the drive rod being configured to drive the cover plate to move vertically

Preferably, the end of the drive rod away from the spacer is provided with a helical thread, by means of which the drive rod is connected to the cover plate, the drive rod being configured to converse a vertical movement of the drive rod into a horizontal movement of the cover plate via the helical thread.

Preferably, the spacer is embodied as a sealed bellows in which the first air chamber is formed, between which and the cylinder the second air chamber is formed, the sealed bellows being extended or shortened under gas pressure in the first air chamber and the second air chamber, the sealed bellows being provided with the drive rod for the cover plate at a side in the first air chamber , the drive rod being configured to drive the cover plate to move so as to close or open the cavity of the crucible body.

Preferably, the spacer is embodied as a seal sheet fitted against side wall of the cylinder, the first air chamber being formed at one side of the seal sheet, and the second air chamber being formed at the other side of the seal sheet, the seal sheet being movable in the cylinder under pressure in the first air chamber and the second air chamber, the seal sheet being connected to the drive rod at a side in the first air chamber.

Preferably, the crucible body has a cylindrical structure, or a cubic structure or a cuboid structure.

Preferably, the first valve and/or the second valve are/is disposed at an end of corresponding air chamber perpendicular to the moving direction of the spacer.

According to another aspect, the disclosure further relates to a method for filling the hermetic sealed crucible, comprising the following steps:

Step 1: filling an inert gas into the glove box until an atmospheric pressure;

Step 2: placing the hermetic sealed crucible and a material to be filled into the glove box, opening the first valve and the second valve such that a pressure P1 in the first air chamber and a pressure P2 in the second air chamber are the same and equal to the atmospheric pressure, opening the hermetic sealed crucible to fill the material into the cavity in the hermetic sealed crucible;

Step 3: placing the hermetic sealed crucible into a transition chamber of the glove box, evacuating the transition chamber until it has a pressure less than 1 bar rather than be in a vacuum state, closing the second valve such that the pressure P1 in the first air chamber and the pressure P2 in the second air chamber are the same and less than the atmospheric pressure;

Step 4: filling the inert gas into the transition chamber until the atmospheric pressure such that the pressure P1 in the first air chamber is greater than the pressure P2 in the second air chamber and equal to the atmospheric pressure; the spacer in the hermetic sealed crucible bringing the cover plate to seal the cavity in the hermetic sealed crucible.

Step 5: taking the hermetic sealed crucible out of the glove box.

The method for filling the hermetic sealed crucible further comprises steps of opening the hermetic sealed crucible, comprising a step of opening the first valve and the second valve such that the pressure P1 in the first air chamber is equal to the pressure P2 in the second air chamber.

According to another aspect, the present disclosure further relates to an vapor deposition method, comprising a step of placing the filled hermetic sealed crucible into a processing chamber of the vapor deposition device, the filling being implemented by the above method.

The vapor deposition method of the disclosure exhibits the following advantageous aspects.

Preferably, the method comprises a step of placing the hermetic sealed crucible into the processing chamber, and further comprises a step of evacuating the processing chamber such that the pressure P2 in the second air chamber is greater than the pressure P1 in the first air chamber to open the hermetic sealed crucible.

Preferably, the method comprises a step of stopping vapor deposition in which a protective gas is filled into the processing chamber first when it is required to stop the vapor deposition and open the processing chamber such that when the pressure in the processing chamber is greater than the pressure P2 in the second air chamber, the pressure P1 in the first air chamber is greater than the pressure P2 in the second air chamber and the cover plate is movable relative to the crucible body to close the cavity in the crucible body.

The hermetic sealed crucible and the vapor deposition method of the disclosure can ensure that an operator is entirely out of contact with the material during the filling process and can ensure safety of the operator, and that the material is under the protection of the insert gas to prevent the material from being deteriorated due to water adsorption or oxidization caused by exposure to air. The hermetic sealed crucible and the vapor deposition method of the disclosure further can reduce filling time and reduce human and time consumption.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a schematic perspective view of a hermetic sealed crucible of the disclosure;

FIG. 2 is a structural view of a pneumatic driver of the hermetic sealed crucible according to an embodiment of the disclosure, wherein the spacer 7 is a closed bellows

FIG. 3 is a structural view of a pneumatic driver of the hermetic sealed crucible according to another embodiment of the disclosure, wherein the spacer 7 is a seal sheet;

FIG. 4 is a flow chart showing filling of the hermetic sealed crucible according to the disclosure.

Corresponding reference numerals indicate corresponding parts or features throughout the several views of the drawings.

### DETAILED DESCRIPTION

Example embodiments will now be described more fully with reference to the accompanying drawings.

The structures of a hermetic sealed crucible according to the embodiments of the disclosure as well as various aspects thereof will be illustrated below with reference to the drawings. More details are depicted below to help an ordinary skilled in the art understand the disclosure more comprehensively. However, it is obvious to an ordinary skilled in the art that the embodiments of the disclosure can be carried out without some of the details. Besides, it should be understood that the disclosure is not limited to the introduced particular embodiments. In contrast, any combination of the following features and elements may be considered to implement the disclosure, no matter whether they refer to different embodiments. Therefore, the following aspects, features, embodiments and advantages are intended for illustration only but shall not be taken as elements or limitations to the claims, unless explicitly specified otherwise.

It should be understood that the technical terms “center”, “longitudinal”, “transverse”, “upper”, “lower”, “front”, “rear”, “left”, “right”, “vertical”, “horizontal”, “top”, “bottom”, “inner”, “outer” and etc. herein refer to the location or position relation shown in the drawings, which are only intended to illustrate the invention and simplify the illustration but shall not be taken as limitations to the disclosure.

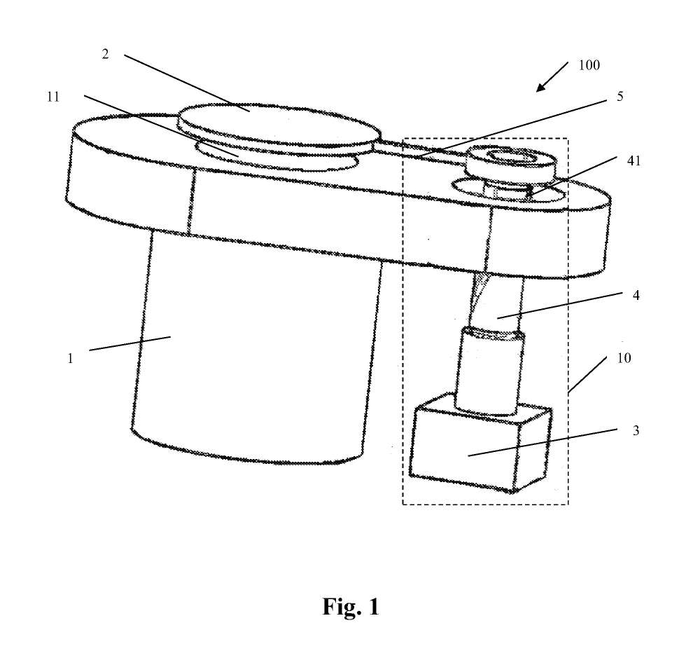

FIG. 1 shows a hermetic sealed crucible 100 according to a preferred embodiment of the present disclosure, the hermetic sealed crucible comprising a cylindrical crucible body 1 in which a cylindrical cavity 11 is disposed for housing an vapor deposition material, a cover plate 2 being disposed at an opening of the cavity 11 and being capable of moving relative to the opening of the cavity 11 to close and open the cavity 11.

Although the crucible body 1 and the cavity 11 in the illustrated embodiment have a cylindrical shape, it is possible to envisage that the crucible body 1 and the cavity 11 may be in any shape, e.g. cubic or cuboid shape. The shape of the cover plate 2 corresponds to that of the opening of the cavity 11.

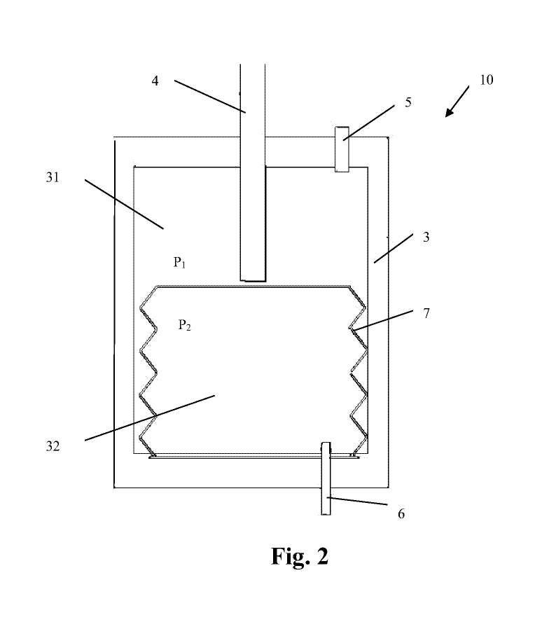

The cover plate 2 is connected to a pneumatic driver 10 that drives the cover plate 2 to move relative to the opening of the cavity 11. The pneumatic driver 10 is configured as shown in FIG. 2, comprising a cylinder 3 in which a spacer 7 is arranged to divide the cylinder 3 into a first air chamber 31 and a second air chamber 32, the spacer 7 being movable under different air pressures of the first air chamber 31 and the second air chamber 32 at either side; a drive rod 4 is disposed on the spacer 7 in the first air chamber 31 such that the drive rod 4 can be moved up and down by the spacer 7. One end of the drive rod 4 extends out of the cylinder 3 and connects to the cover plate 2 to drive the cover plate 2 to move relative to the opening in the cavity 11. A first valve 5 and a second valve 6 are disposed in the first air chamber 31 and the second air chamber 32 respectively to communicate the first air chamber 31 and the second air chamber 32 with ambient air.

An opening is used to replace the first valve 5 such that the first air chamber 31 is constantly in communication with atmosphere outside. The first valve 5 is designed such that the pressures in the first air chamber 31 and the second air chamber 32 exhibit more possibilities to enable more operations.

The first valve 5 and the second valve 6 are both arranged at ends of corresponding air chambers as shown in the drawing, but it is possible to envisage that they may be disposed in other positions of the respective air chambers without affecting the operation of the closed crucible.

The drive rod 4 can be rested against an end face of the spacer 7 directly without fixed connection, or may be fixedly connected with the spacer 7 by adhering or welding and the like, or may be formed into one piece with the spacer 7.

In the embodiments of FIGS. 1 and 2, when the pressure P2 in the second air chamber is greater than the pressure P1 in a first air chamber, the volume of the second air chamber is increasing gradually and the pressure P2 in the second air chamber pushes the spacer 7 to move upward to further bring the drive rod 4 upward which then drives the cover plate 2 connected thereto to move so as to open the opening in the cavity 11 of the crucible body 1. When the pressure P1 in the first air chamber is greater than the pressure P2 in the second air chamber, the volume of the first air chamber is increasing gradually and the pressure P1 in the first air chamber pushes the spacer 7 to move downward to move the drive rod 4 downward which drives the cover plate 2 connected thereto to move so as to close the opening in the cavity 11 of the crucible body 1.

In the embodiments shown in FIGS. 1 and 2, the drive rod 4 is fixedly connected to the cover plate 2 at an extending end to drive the cover plate 2 to move up and down relative to the cavity 11 of the crucible body 1, thereby opening and closing the cavity 11.

It is possible to envisage that a transmission mechanism may be arranged to transfer up-and-down movement of the drive rod 4 to movement of the cover plate 2 within a horizontal plane to open and close the cavity 11. For instance, the drive rod 4 is provided with a helical thread 41, and the cover plate 2 and the drive rod 4 are connected in such a manner that a vertical movement of the drive rod 4 is changed into a horizontal movement of the cover plate 2 by using the helical thread 41 to open or close the cavity in the crucible body 1. It is possible to envisage that the transmission mechanism may be any other means that can be conceived.

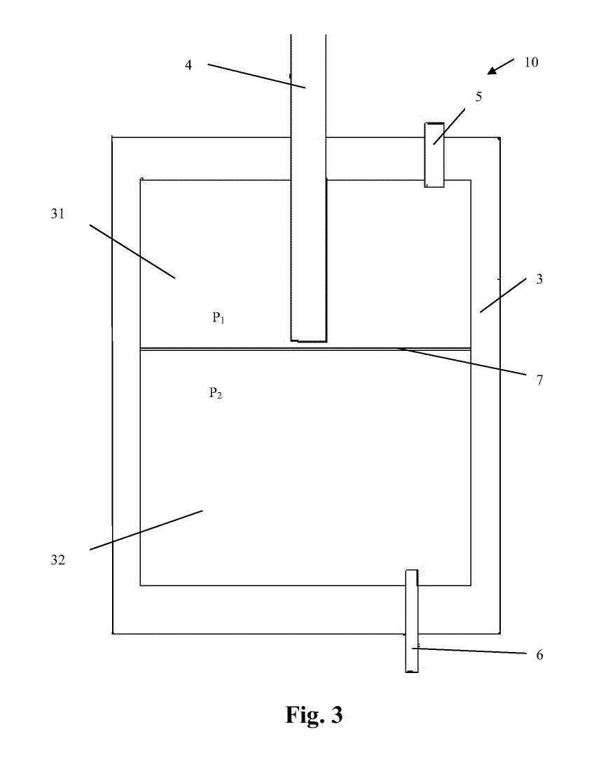

In an example of the pneumatic drive 10 shown in FIG. 2, the spacer 7 is a sealed bellows between the out surface of which and a wall of the cylinder 3 the first air chamber 31 is formed and inside of which a second air chamber 32 is formed; the sealed bellows can be extended or shortened under the pressure P1 in the first air chamber 31 and the pressure P2 in the second air chamber 32 to drive the drive rod 4 at the end of the sealed bellows to move. It is possible to envisage that the spacer 7 may be in other structure capable of moving with the pressure, as such as a seal sheet fitted against a wall of the cylinder 3 as shown in FIG. 3. The first air chamber 31 is formed at a side of the seal sheet, and the second air chamber 32 is formed at the other side of the seal sheet. The seal sheet is able to move within the cylinder under the pressure P1 in the first air chamber 31 and the pressure P2 in the second air chamber 32. At the side in the first air chamber 31 the seal sheet is provided and connected to the drive rod 4 that moves with the movement of the seal sheet. The spacer 7 in the form of the sealed bellows can ensure excellent sealing between the first air chamber 31 and the second air chamber 32.

With reference to the vapor deposition process of the display panel, a method of using the hermetic sealed crucible will be introduced below.

Filling of the hermetic sealed crucible 100 needs a glove box (now shown) which usually consists of a main box and a transition chamber. The main box is provided with two (or more) glove operation interfaces such that the glove box can be operated by one (or several) people to improve use efficiency of the box. A valve open into the transition chamber is provided with a deflation and inflation nipple which is effective when the transition chamber is required to be deflated or inflated. A valve and a nipple are mounted on the main box and can be used when a user inflates or deflates the main box. As transition space between the main box and the outside thereof, the transition chamber is formed by two seal gates (leading to the main box and the outside thereof respectively) and two valves (leading to the main box and the outside thereof respectively) and a chamber body, wherein the two seal gates can isolate the main box from the ambient. By virtue of the glove box in which an inert gas is charged, the crucible can be filled in the case of isolating air.

A method of filling the hermetic sealed crucible of the disclosure comprises the following steps:

Step S1: filling an inert gas into the glove box until an atmospheric pressure;

Step S2: placing the hermetic sealed crucible and a material to be filled into the glove box, opening the first valve 5 and the second valve 6 such that the pressure P1 in the first air chamber 31 and the pressure P2 in the second air chamber 32 are the same and equal to the atmospheric pressure, and that with equal pressures at both sides of the spacer 7, the cover plate 2 can be operated manually. The hermetic sealed crucible is opened manually in the glove box at glove operation interfaces to fill the material into the cavity of the hermetic sealed crucible (the hermetic sealed crucible can be closed manually after manual filling of the material into the cavity, but it may not be closed);

Step S3: moving hermetic sealed crucible from the main box of the glove box to the transition chamber, closing the seat gate and valve between the transition chamber and the main box, deflating the transition chamber to a semi-vacuum state, closing the second valve 6 such that the second air chamber 32 is not in communication with the atmosphere in the glove box, while the first air chamber 31 is still in communication with the atmosphere in the glove box, and the pressure P1 in the first air chamber and the pressure P2 in the second air chamber are the same and less than the atmospheric pressure;

Step S4: filling the inert gas into the transition chamber to the atmospheric pressure. Now the pressure P1 in the first air chamber is equal to the pressure in the transition chamber and greater than the pressure P2 in the second air chamber; the volume of the first air chamber 31 is increased such that the spacer 7 is moved downward which drives the cover plate 2 to seal the cavity 11 of the hermetic sealed crucible. Furthermore, the pressure P1 in the first air chamber 31 that is greater than the pressure P2 in the second air chamber 32 presses the cover plate 2 firmly against the opening in the cavity 11, such that the cavity 11 cannot be opened manually. If the hermetic sealed crucible is closed manually in step S1, the cover 2 in this step does not move any longer but is pressed firmly against the opening in the cavity 11 by the pressure P1.

Step S5: taking the hermetic sealed crucible 100 filled with the material out of the glove box. The hermetic sealed crucible 100 now is sealed and in an unopened state, the first air chamber 31 is in communication with atmosphere, and the second chamber 32 is not in communication with atmosphere. Moreover, the pressure P1 in the first air chamber 31 is greater than the pressure in the second air chamber 32 such that the cover plate 2 is firmly pressed against the opening in the cavity under the pressures P1 and P2.

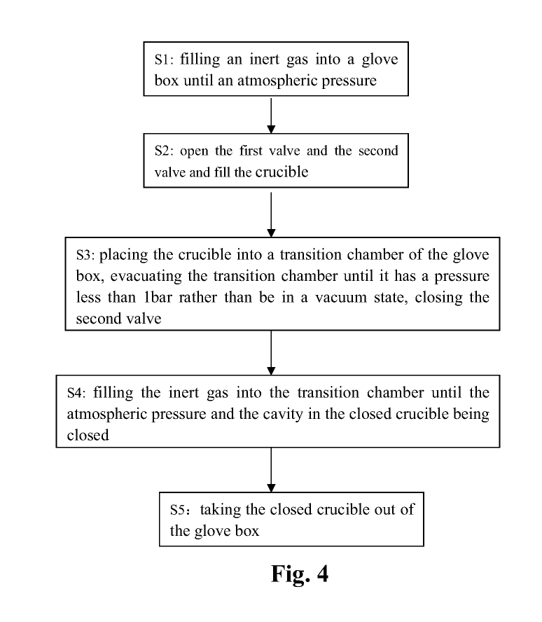

The flow chart of the above method is shown in FIG. 4.

It can be seen from the above illustration that in the process of filling the hermetic sealed crucible 100 of the disclosure, the operator always keeps out of direct contact with the material to ensure safety of the operator. Meanwhile, the material to be filled is out of contact with the atmosphere before, after or during the filling to prevent deterioration of the material caused by absorption of vapor from air and/or oxidization by air, thereby ensuring quality of the filled material. Thanks to the hermetic sealed crucible of the disclosure, the filling process becomes simple with decreased filling time, which saves human labor and time consumption.

The hermetic sealed crucible is placed in the processing chamber of the vapor deposition device after being filled and vacuum the processing chamber. Then the first air chamber 31 is in communication with atmosphere in the processing chamber, so the pressure P1 in the first air chamber 31 is equal to the pressure inside the processing chamber and less than the pressure P2 in the second air chamber 32. The volume of the first air chamber 31 is decreasing gradually and the volume of the second air chamber 32 is increasing gradually to push the spacer 7 to move upward such that the cover plate 2 is moved relative to the opening of the cavity 11 to open the hermetic sealed crucible. In this case, the material required for vapor deposition is exposed to the atmosphere in the processing chamber, then the vapor deposition process goes on according to the method known by an ordinary in the art.

In the event of an accident or finish of the vapor deposition, the vapor deposition has to be stopped to open the processing chamber, and a protective gas is filled into the processing chamber first. When the pressure in the processing chamber exceeds the pressure P2 in the second air chamber, the pressure P1 in the first air chamber (equal to the pressure in the processing chamber) is greater than the pressure P2 in the second air chamber to allow the cover 2 to seal the cavity 11 in the crucible body 1 and thus seal the crucible. Now the processing chamber can be opened to treat the crucible therein. Apparently, when the hermetic sealed crucible 100 of the disclosure is used for vapor deposition, the operator will not contact with the material in the crucible before placing the crucible in the processing chamber and during the process of taking the crucible out after the vapor deposition, which ensures safety of the operator and prevents the material in the hermetic sealed crucible 100 from being deteriorated.

When the hermetic sealed crucible of the disclosure needs to be opened, the first valve 5 and the second valve 6 have to be opened to communicate with the air outside such that the pressure P1 in the first air room is equal to the pressure P2 in the second air chamber, and the pressures at both sides of the spacer 7 are equal, thereby opening the hermetic sealed crucible automatically.

Although the hermetic sealed crucible 100 of the disclosure is depicted in combination with the vapor deposition process, it is possible to envisage that the hermetic sealed crucible 100 can be applied to any non-contact filling or other applications.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. A hermetic sealed crucible, comprising
a crucible body with a cavity for placing materials;
a cover plate for covering and sealing the cavity of the crucible body,
characterized in that the hermetic sealed crucible further comprises a pneumatic driver which is connected to the cover plate and drives the cover plate to move relative to the cavity in the crucible body to open and close the cavity in the crucible body,
the pneumatic device is configured in such a manner that it comprises a cylinder in which a spacer is arranged, the spacer being configured to move relative to the cylinder under pressure and divide the cylinder into a first air chamber provided with a first valve in communication with ambient, and a second air chamber provided with a second valve in communication with the ambient, the spacer being provided with a drive rod connected to the cover plate at a side in the first air chamber, the drive rod being configured to drive the cover plate to move to close or open the cavity on the crucible body.

2. A hermetic sealed crucible according to claim 1, characterized in that the first valve is replaced by an opening such that the first air chamber is constantly in communication with the ambient.

3. A hermetic sealed crucible according to claim 1, characterized in that the drive rod is fixedly connected to the cover plate at a side in the first air chamber, the drive rod being configured to drive the cover plate to move vertically.

4. A hermetic sealed crucible according to claim 1, characterized in that the end of the drive rod away from the spacer is provided with a helical thread, by means of which the drive rod is connected to the cover plate, the drive rod being configured to converse a vertical movement of the drive rod into a horizontal movement of the cover plate via the helical thread.

5. A hermetic sealed crucible according to claim 1, characterized in that the spacer is embodied as a sealed bellows in which the first air chamber is formed, between which and the cylinder the second air chamber is formed, the sealed bellows being extended or shortened under pressure in the first air chamber and the second air chamber, the sealed bellows being provided with the drive rod for the cover plate at a side in the first air chamber, the drive rod being configured to drive the cover plate to move so as to close or open the cavity of the crucible body.

6. A hermetic sealed crucible according to claim 1, characterized in that the spacer is embodied as a seal sheet fitted against side wall of the cylinder, the first air chamber being formed at a side of the seal sheet, and the second air chamber being formed at the other side of the seal sheet, the seal sheet being movable in the cylinder under pressure in the first air chamber and the second air chamber, the seal sheet being connected to the drive rod at a side in the first air chamber.

7. A hermetic sealed crucible according to claim 1, characterized in that the crucible body has a cylindrical structure, or a cubic structure or a cuboid structure.

8. A hermetic sealed crucible according to claim 1, characterized in that the first valve and/or the second valve are/is disposed at an end of corresponding air chamber perpendicular to the moving direction of the spacer.

9. A method for filling the hermetic sealed crucible according to claim 1, characterized in that it comprises the following steps:
Step 1: filling an inert gas into a glove box until an atmospheric pressure;
Step 2: placing the hermetic sealed crucible and a material to be filled into the glove box, opening the first valve and the second valve such that a pressure P1 in the first air chamber and a pressure P2 in the second air chamber are the same and equal to the atmospheric pressure, opening the hermetic sealed crucible to fill the material into the cavity in the hermetic sealed crucible;
Step 3: placing the hermetic sealed crucible into a transition chamber of the glove box, evacuating the transition chamber until it has a pressure less than 1 bar rather than be in a vacuum state, closing the second valve such that the pressure P1 in the first air chamber and the pressure P2 in the second air chamber are the same and less than the atmospheric pressure;
Step 4: filling the inert gas into the transition chamber until the atmospheric pressure such that the pressure P1 in the first air chamber is greater than the pressure P2 in the second air chamber and equal to the atmospheric pressure; the spacer in the hermetic sealed crucible bringing the cover plate to seal the cavity in the closed crucible;
Step 5: taking the closed crucible out of the glove box.

10. A method for filling the hermetic sealed crucible according to claim 9, further comprising steps of opening the hermetic sealed crucible, characterized in that it comprises a step of opening the first valve and the second valve such that the pressure P1 in the first air chamber is equal to the pressure P2 in the second air chamber.

11. A vapor deposition method, characterized in that it comprises a step of placing the filled hermetic sealed crucible into a processing chamber of the vapor deposition device, the filling being implemented by the method of claim 9.

12. A vapor deposition method according to claim 11, characterized in that it comprises a step of placing the hermetic sealed crucible into the processing chamber, and further comprising a step of evacuating the processing chamber such that the pressure P2 in the second air chamber is greater than the pressure P1 in the first air chamber to open the hermetic sealed crucible.

13. A vapor deposition method according to claim 11, characterized in that it comprises a step of stopping vapor deposition, in which a protective gas is filled into the processing chamber first when it is required to stop the vapor deposition and open the processing chamber such that when the pressure in the processing chamber is greater than the pressure P2 in the second air chamber, the pressure P1 in the first air chamber is greater than the pressure P2 in the second air chamber and the cover plate is movable relative to the crucible body to close the cavity in the crucible body.

14. A vapor deposition method, characterized in that it comprises a step of placing the filled hermetic sealed crucible into a processing chamber of the vapor deposition device, the filling being implemented by the method of claim 10.

15. A vapor deposition method according to claim 14, characterized in that it comprises a step of placing the hermetic sealed crucible into the processing chamber, and further comprising a step of evacuating the processing chamber such that the pressure P2 in the second air chamber is greater than the pressure P1 in the first air chamber to open the hermetic sealed crucible.

16. A vapor deposition method according to claim 14, characterized in that it comprises a step of stopping vapor deposition, in which a protective gas is filled into the processing chamber first when it is required to stop the vapor deposition and open the processing chamber such that when the pressure in the processing chamber is greater than the pressure P2 in the second air chamber, the pressure P1 in the first air chamber is greater than the pressure P2 in the second air chamber and the cover plate is movable relative to the crucible body to close the cavity in the crucible body.
